(19) United States
(12) Patent Application Publication
(10) Pub. No.: US 2024/0404793 A1
(43) Pub. Date: Dec. 5, 2024

(54) SUBSTRATE TREATING APPARATUS AND FLUID SUPPLY UNIT

(71) Applicant: SEMES CO., LTD., Cheonan-si (KR)

(72) Inventors: Wook Sang JANG, Yongin-si (KR); Jae Woong SIM, Hwaseong-si (KR); Dong Uk KIM, Hwaseong-si (KR); In Hoe KIM, Yongin-si (KR)

(73) Assignee: SEMES CO., LTD., Cheonan-si (KR)

(21) Appl. No.: 18/413,805

(22) Filed: Jan. 16, 2024

(30) Foreign Application Priority Data
Jun. 1, 2023 (KR) 10-2023-0070777

(51) Int. Cl. H01J 37/32

(52) U.S. Cl. CPC H01J 37/3244; H01J 2237/002; H01J 2237/24585

(57) ABSTRACT

Disclosed are a substrate treating apparatus and a fluid supply unit that reduce the outer diameter while preventing condensation from occurring even without wrapping a pipe supplying a refrigerant with a heat insulating material. The substrate treating apparatus includes: a process chamber having a treatment space for treating a substrate; an inner pipe connected to the process chamber and for supplying a heat exchange fluid to an interior of the process chamber; a cooler connected to the inner pipe, and for cooling the heat exchange fluid and supplying the cooled heat exchange fluid to the inner pipe; an outer pipe disposed on an outer side of the inner pipe while surrounding the inner pipe to form a suction space between the inner pipe and the outer pipe; an intake part connected to the suction space, and for sucking the suction space; and a spacing maintaining part disposed in the suction space, and for maintaining a spacing distance between the inner pipe and the outer pipe.

### CROSS-REFERENCE TO RELATED APPLICATIONS

This application claims priority to and the benefit of Korean Patent Application No. 10-2023-0070777 filed in the Korean Intellectual Property Office on Jun. 1, 2023 the entire contents of which are incorporated herein by reference.

### TECHNICAL FIELD

The present disclosure relates to a substrate treating apparatus and a fluid supply unit, and more particularly, to a substrate treating apparatus and a fluid supply unit for treating a substrate.

### BACKGROUND ART

Plasma refers to an ionized gas state composed of ions, radicals, and electrons. Plasma is generated by very high temperatures, strong electric fields, or RF Electromagnetic Fields. A semiconductor device fabrication process may include an etching process that utilizes plasma to remove a thin film formed on a substrate, such as a wafer. The etching process is performed in which ions and/or radicals of plasma collide with the thin film on the substrate or react with the thin film.

When the substrate is treated with plasma, the straightness of the ions and/or radicals included in the plasma is important. The straightness of the ions and/or radicals contained in the plasma is an important factor in determining the selectivity of the substrate. When the substrate is treated to improve the straightness of the ions and/or radicals, the temperature of the electrostatic chuck supporting the substrate is lowered. Thus, the etch rate of the substrate is improved.

In a substrate treating apparatus in the related art that treats a substrate by lowering the temperature of the electrostatic chuck, while treating the substrate with plasma, impurities, such as particles, may be generated due to the reaction of the plasma with the thin films formed on the substrate. In particular, in the process of treating the substrate with plasma by keeping the temperature of the electrostatic chuck low, the temperature change of the substrate is intensified, and impurities may be generated in large quantities due to this temperature change. The generated impurities may adhere to the substrate or adhere to the top surface of a support unit. Impurities adhering to the top surface of the support unit may again adhere to the underside of the substrate when the substrate is lifted after the plasma treatment has ended. Impurities adhering to the substrate lead to process defects in subsequent processes.

Accordingly, the substrate treating apparatus in the related art treats the substrate by forming plasma with a very low temperature. In this case, the substrate treating apparatus cools the substrate by supplying a refrigerant to the support unit supporting the substrate. For example, the temperature of the refrigerant may be −30° C. or lower.

Therefore, as condensation is generated in the area around a pipe supplying a refrigerant due to the temperature difference between the outside of the pipe and the interior of the pipe, it is necessary to wrap the pipe with a very thick heat insulation material to prevent condensation from forming around the pipe.

However, this method of wrapping very thick heat insulation materials around the pipe increases the overall thickness of the pipe too much, making it difficult to find space for mounting the pipe.

Furthermore, the pipe is subject to shrinkage due to the refrigerant forming at a very low temperature, and there is a problem in that the shrunk pipe is bent.

### SUMMARY OF THE INVENTION

A technical object of the present disclosure to solve the foregoing problems is to provide a substrate treating apparatus and a fluid supply unit that reduce an outer diameter while preventing condensation from occurring even without wrapping a pipe supplying a refrigerant with a heat insulating material.

The object of the present disclosure is not limited thereto, and other objects not mentioned will be clearly understood by those of ordinary skill in the art from the following description.

An exemplary embodiment of the present disclosure provides a substrate treating apparatus including: a process chamber having a treatment space for treating a substrate; an inner pipe connected to the process chamber and for supplying a heat exchange fluid to an interior of the process chamber; a cooler connected to the inner pipe, and for cooling the heat exchange fluid and supplying the cooled heat exchange fluid to the inner pipe; an outer pipe disposed on an outer side of the inner pipe while surrounding the inner pipe to form a suction space between the inner pipe and the outer pipe; an intake part connected to the suction space, and for sucking the suction space; and a spacing maintaining part disposed in the suction space, and for maintaining a spacing distance between the inner pipe and the outer pipe.

According to the exemplary embodiment, the spacing maintaining part may make the inner pipe be spaced apart at a certain extent of the suction space to make a center axis of the inner pipe match or be adjacent to a center axis of the outer pipe.

According to the exemplary embodiment, the inner pipe and the outer pipe may not be in direct contact with each other.

According to the exemplary embodiment, the spacing maintaining part may be provided with a passage area formed so that the suction spaces located on both sides of the spacing maintaining parts communicate with each other.

According to the exemplary embodiment, the spacing maintaining part may extend while forming a path having at least one bent from the inner pipe to the outer pipe.

According to the exemplary embodiment, the spacing maintaining part may include: a connecting body coupled to each of the inner pipe and the outer pipe and formed in plural; and a cylindrical body coupled between the connecting bodies.

According to the exemplary embodiment, the connecting body may be coupled only to a partial region when is coupled to the cylindrical body.

According to the exemplary embodiment, the connecting bodies may include at least two connecting bodies that are not aligned on the same line based on an outer peripheral direction of the inner pipe and the outer pipe.

According to the exemplary embodiment, the cylindrical body may be provided with a plurality of through-holes.

According to the exemplary embodiment, the spacing maintaining part may be coupled to the inner pipe and is coupled to the outer pipe.

According to the exemplary embodiment, the substrate treating apparatus may further include: a temperature sensor unit coupled to the outer pipe and for measuring a temperature of the outer pipe; and a leak detection unit which is interlocked with the temperature sensor unit and generates a leak alarm when the temperature of the outer pipe falls below a preset temperature value.

According to the exemplary embodiment, the substrate treating apparatus may further include: a pressure sensor unit connected with the suction space while being in communication with the suction space, and for measuring a pressure of the suction space; and a leak detection unit which is interlocked with the pressure sensor unit and generates a leak alarm when the pressure of the suction space is higher than a preset pressure.

According to the exemplary embodiment, the substrate treating apparatus may further include a purge port part connected to a branch point of the inner pipe to purge a heat exchange fluid flowing in the inner pipe to an outer side of the outer pipe, and forming a path bent multiple times on the outer side of the inner pipe.

According to the exemplary embodiment, the purge port part may include: a valve for purge installed between the branch points of the inner pipe; a pipe for purge having one end connected with the valve for purge and the other end exposed to an outer side of the outer pipe, and forming a path bent multiple times on the outer side of the inner pipe; and a reflector placed in the suction space and wrapping around an outer side of the pipe for purge.

Another exemplary embodiment of the present disclosure provides a unit for supplying a fluid, the unit including: an inner pipe for supplying a heat exchange fluid; a cooler connected to the inner pipe, and for cooling the heat exchange fluid and supplying the cooled heat exchange fluid to the inner pipe; an outer pipe arranged to surround the inner pipe so as not to be in contact with the inner pipe, and forming a suction space between the inner pipe and the outer pipe; an intake part connected to the suction space, and for sucking the suction space; and an anti-bending part disposed in the suction space, coupled to the outer pipe, and supporting the inner pipe.

According to the exemplary embodiment, the anti-bending part may be disposed between areas in which the inner pipe and the outer pipe are bent.

According to the exemplary embodiment, the inner pipe and the outer pipe may be formed of a rigid material.

According to the exemplary embodiment, the anti-bending part may include: an inner support which surrounds the inner pipe and is in contact with the inner pipe; an outer support which surrounds the inner pipe and is in contact with the outer pipe; and a fastener engaged with the inner support and the outer support to fix the inner support and the outer support to be spaced apart by a certain distance.

According to the exemplary embodiment, the anti-bending part may further include an outer coupling body coupled to at least one of the outer support and the inner support and coupled to the outer pipe.

Still another exemplary embodiment of the present disclosure provides a substrate treating apparatus including: a process chamber having a treatment space for treating a substrate; a support unit for supporting the substrate within the process chamber; an inner pipe connected with the support unit and for supplying a heat exchange fluid to an interior of the support unit; a cooler connected to the inner pipe, and for cooling the heat exchange fluid and supplying the cooled heat exchange fluid to the inner pipe; an outer pipe disposed to surround the inner pipe so as not to be in contact with the inner pipe, forming a suction space between the inner pipe and the outer pipe, and being not in direct contact with the inner pipe; an intake part connected to the suction space and for sucking the suction space; a spacing maintaining part which includes a cylindrical body coupled to each of the inner pipe and the outer pipe, is formed with a plurality of connecting bodies and a plurality of through-holes, and is coupled only to a partial region between the connecting bodies, and which is disposed in the suction space, supports an area between the inner pipe and the outer pipe, is disposed while surrounding the inner pipe in a predetermined extent of the suction space to make a center axis of the inner pipe be adjacent to a center axis of the outer pipe, is formed with a passage area in communication with the suction space, and forms a path bent at least one time from the inner pipe to the outer pipe; a temperature sensor unit coupled to the outer pipe and for measuring a temperature of the outer pipe; a pressure sensor unit connected in communication with the suction space and for measuring a pressure of the suction space; a leak detection unit which interlocks with the temperature sensor unit and generates a leak alarm when a temperature of the outer pipe falls below a preset temperature value, and interlocks with the pressure sensor unit and generates a leak alarm when a pressure in the suction space is higher than a preset pressure; a purge port part including a valve for purge installed between branch points of the inner pipe, a pipe for purge having one end connected with the valve for purge and the other end exposed to an outer side of the outer pipe and forming a path bent multiple times on the outer side of the inner pipe, and a reflector disposed in the suction space and surrounding an outer side of the pipe for purge; and an anti-bending part including an inner support, which is disposed while surrounding the inner pipe and is in contact with the inner pipe, an outer support, which is disposed while surrounding the inner pipe and is in contact with the outer pipe, a fastener, which is coupled to the inner support and the outer support and separates the inner support and the outer support by a certain distance to fix the inner support and the outer support, and an outer coupling body, which is coupled to at least one of the outer support and the inner support and is coupled to the outer pipe.

The present disclosure has the effect of preventing condensation from occurring without wrapping a separate insulating material around the outer side of the inner pipe, and reducing the outer diameter compared to the substrate treating apparatus in the related art because the outer pipe is arranged on the outer side of the inner pipe and the suction space is sucked in by the intake part.

The effect of the present disclosure is not limited to the foregoing effects, and non-mentioned effects will be clearly understood by those skilled in the art from the present specification and the accompanying drawings.

### BRIEF DESCRIPTION OF THE DRAWINGS

FIG. 1 is a top plan view schematically illustrating a substrate treating apparatus according to an exemplary embodiment of the present disclosure.

FIG. 2 is a longitudinal cross-sectional view schematically illustrating a process chamber of FIG. 1 according to the exemplary embodiment.

FIG. 3 is an enlarged perspective view of the peripheral structure of an inner pipe of a fluid supply unit and a collection side inner pipe according to the exemplary embodiment of the present disclosure.

FIG. 4 is a partial cross-sectional view of the incised state of the inner pipe illustrated in FIG. 1.

FIG. 5 is an enlarged partial cross-sectional view of a spacing maintaining part illustrated in FIG. 4.

FIG. 6 is a top plan view of the spacing maintaining part illustrated in FIG. 5.

FIG. 7 is a perspective view of the spacing maintaining part illustrated in FIG. 6.

FIG. 8 is a perspective view of a modified example of a first can body illustrated in FIG. 7.

FIG. 9 is a perspective view of a modified example of a second can body illustrated in FIG. 7.

FIG. 10 is a partial cross-sectional view of an anti-bending part illustrated in FIG. 4, enlarged in the perspective direction.

FIG. 11 is a perspective view of the anti-bending part illustrated in FIG. 10.

FIG. 12 is an exploded perspective view of an inner support and an outer support of the anti-bending part illustrated in FIG. 11.

FIG. 13 is a perspective view of the interior of the outer pipe in which a purge port part illustrated in FIG. 3 is formed.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

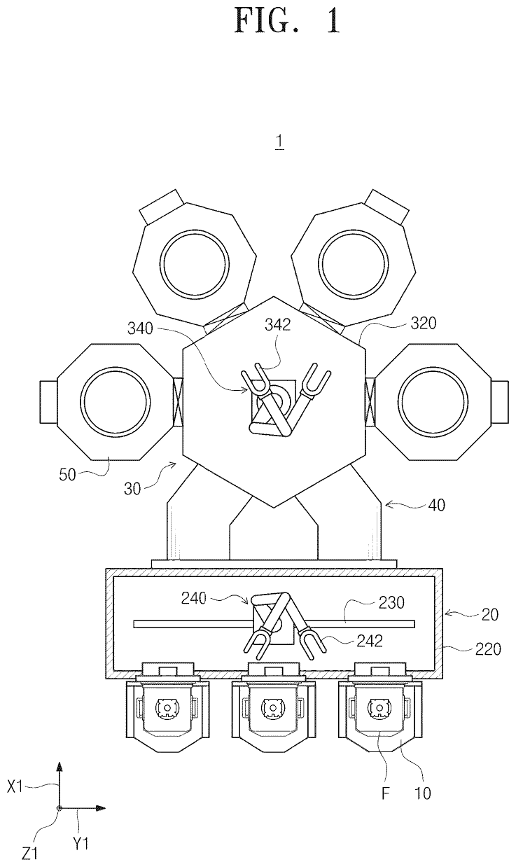

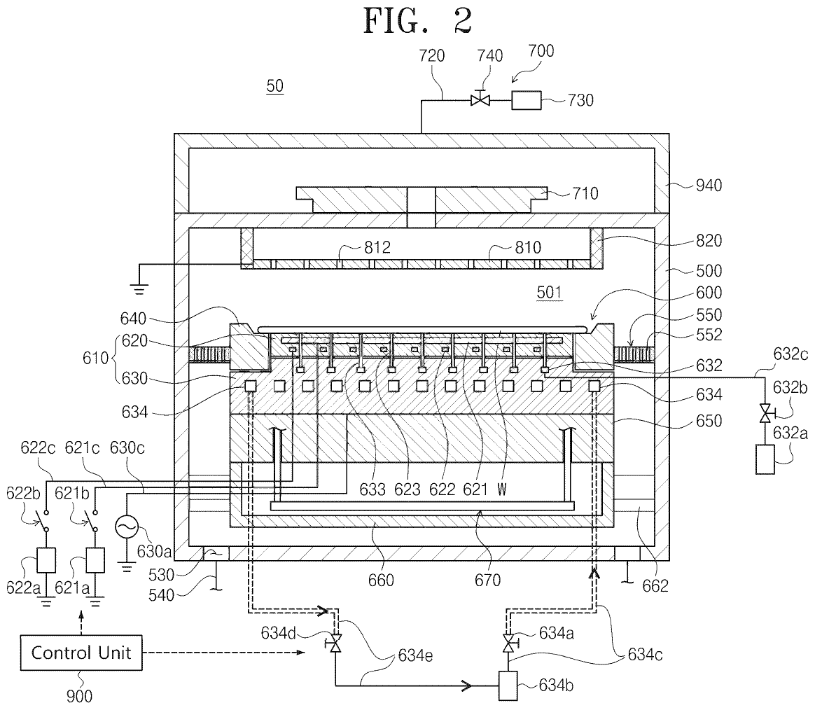

FIG. 1 is a top plan view schematically illustrating a substrate treating apparatus according to an exemplary embodiment of the present disclosure. FIG. 2 is a longitudinal cross-sectional view schematically illustrating a process chamber of FIG. 1 according to the exemplary embodiment.

Referring to FIGS. 1 and 2, a substrate treating apparatus of the present disclosure may include a load port 10, a normal pressure transfer module 20, a vacuum transfer module 30, a load lock chamber 40, and a process chamber 50.

The load port 10 may be disposed on one side of the normal pressure transfer module 20 described later. At least one load port 10 may be disposed on one side of the normal pressure transfer module 20. The number of load ports 10 may be increased or decreased depending on process efficiency and footprint conditions.

A container F may be placed on the load port 10. The container F may be loaded into or unloaded from the load port 10 by a transfer means (not illustrated), such as an Overhead Transfer Apparatus (OHT), an Overhead Conveyor, or an Automated Guided Vehicle, or by an operator. The container F may include various types of containers, depending on the type of articles being stored. As the container F, a hermetically sealed container, such as a Front Opening Unified Pod (FOUP), may be used.

The normal pressure transfer module 20 and the vacuum transfer module 30 may be disposed along a first direction X1. Here, the first direction X1 is perpendicular to a second direction Y1, and the plane including the first direction X1 and the second direction Y1 is defined as a plane parallel to the ground. Also, the direction perpendicular to the plane including the first direction X1 and the second direction Y1 is defined as a third direction Z1. Furthermore, a plane including the second direction Y1 and the third direction Z1 is defined as a front plane, and a plane including the first direction X1 and the third direction Z1 is defined as a left plane, and a six-sided view is defined based on the front plane, the plane, and the left plane. In this case, the terms, top and bottom, will be described relative to the third direction Z1 perpendicular to the plane.

The normal pressure transfer module 20 may transfer the substrate W between the container F and the load lock chamber 40 described later. According to the exemplary embodiment, the normal pressure transfer module 20 may withdraw the substrate W from the container F and transfer the substrate W to the load lock chamber 40, or may withdraw the substrate W from the load lock chamber 40 and return the substrate W to the interior of the container F.

The normal pressure transfer module 20 may include a transfer frame 220 and a first transfer robot 240. The transfer frame 220 may be disposed between the load port 10 and the load lock chamber 40. The load port 10 may be connected to the transfer frame 220. The internal atmosphere of the transfer frame 220 may be maintained at normal pressure. According to the exemplary embodiment, the interior of the transfer frame 220 may be configured with an atmospheric pressure atmosphere.

The transfer frame 220 is disposed with a transfer rail 230. The longitudinal direction of the transfer rail 230 may be horizontal to the longitudinal direction of the transfer frame 220. A first transfer robot 240 may be positioned on the transfer rail 230.

The first transfer robot 240 may transfer the substrate W between the container F seated on the load port 10 and the load lock chamber 40 described later. The first transfer robot 240 may move forward and backward in the second direction Y1 along the transfer rail 230. The first transfer robot 240 may move in a vertical direction (for example, the third direction Z1). The first transfer robot 240 includes a first transfer hand 242 that moves forward, backward, or rotates in a horizontal plane. On the first transfer hand 242, the substrate W is placed. The first transfer robot 240 may have a plurality of first transfer hands 242. The plurality of first transfer hands 242 may be spaced apart from each other in a vertical direction.

The vacuum transfer module 30 may be disposed between the load lock chamber 40 and the process chamber 50, which will be described later. The vacuum transfer module 30 may include a transfer chamber 320 and a second transfer robot 340.

The internal atmosphere of the transfer chamber 320 may be maintained at vacuum pressure. The second transfer robot 340 may be disposed in the transfer chamber 320. For example, the second transfer robot 340 may be disposed in the center of the transfer chamber 320. The second transfer robot 340 transfers the substrate W between the load lock chamber 40 and the process chamber 50, described later. Additionally, the second transfer robot 340 may transfer the substrate W between the process chambers 50.

The second transfer robot 340 may move in the vertical direction (for example, the third direction Z1). The second transfer robot 340 may include a second transfer hand 342 that moves forward, backward, or rotates in a horizontal plane. On the second transfer hand 342, the substrate W is placed. The second transfer robot 340 may have a plurality of second transfer hands 342. The plurality of second transfer hands 342 may be spaced apart from each other in a vertical direction.

The transfer chamber 320 may be coupled to at least one process chamber 50 described later. According to the exemplary embodiment, the transfer chamber 320 may be polygonal in shape. In a circumference of the transfer chamber 320, the load lock chamber 40 and the process chamber 50, which are described below, may be disposed. For example, as illustrated in FIG. 1, a hexagonal-shaped transfer chamber 320 may be disposed in the center of the vacuum transfer module 30, and the load lock chamber 40 and the process chamber 50 may be disposed along the circumference of the transfer chamber 320. As described above, the shape of the transfer chamber 320 and the number of process chambers 50 may be varied according to user requirements or process requirements.

The load lock chamber 40 may be disposed between the transfer frame 220 and the transfer chamber 320. The load lock chamber 40 has a buffer space, where the substrate W is exchanged, between the transfer frame 220 and the transfer chamber 320. For example, the substrate W that has completed a predetermined treatment in the process chamber 50 may temporarily stay in the buffer space of the load lock chamber 40. Also, the substrate W that have been withdrawn from the container F and are scheduled for a predetermined treatment may temporarily stay in the buffer space of the load lock chamber 40.

As mentioned above, the internal atmosphere of the transfer frame 220 may be maintained at atmospheric pressure, and the internal atmosphere of the transfer chamber 320 may be maintained at vacuum pressure. Accordingly, the load lock chamber 40 is disposed between the transfer frame 220 and the transfer chamber 320 such that the internal atmosphere of the load lock chamber 40 may be switched between atmospheric pressure and vacuum pressure.

The process chamber 50 is connected to the transfer chamber 320. There may be a plurality of process chambers 50. The process chamber 50 may be a chamber that performs a predetermined process on the substrate W. According to the exemplary embodiment, the process chamber 50 may treat the substrate W by using plasma. For example, the process chamber 50 may be a chamber for performing an etching process to remove a thin film on the substrate W, an ashing process to remove a photoresist film, a deposition process to form a thin film on the substrate W, a dry cleaning process, an Atomic Layer Deposition (ALD) process to deposit an atomic layer on the substrate W, or an Atomic Layer Etching (ALE) process to etch an atomic layer on the substrate W using a plasma. However, without limitation, the plasma treatment process performed in the process chamber 50 may be varied to any known plasma treatment process.

The process chamber 50 according to the exemplary embodiment may plasma treat the substrate W. The process chamber 50 includes a housing 500, a support unit 600, a gas supply unit 700, a shower head unit 800, and a control unit 900.

The housing 500 may have an internally sealed shape. The housing 500 has a treatment space 501 for treating the substrate W therein. The treatment space 501 may be maintained in a largely vacuum atmosphere during treatment of the substrate W. The material of the housing 500 may include metal. In the exemplary embodiment, the material of the housing 500 may include aluminum. The housing 500 may be grounded.

An inlet (not illustrated) may be formed in one sidewall of the housing 500. The inlet (not illustrated) functions as a space for the substrate W to loaded in or unloaded from the treatment space 501. The inlet (not illustrated) may be selectively opened and closed by a door assembly (not illustrated).

An exhaust hole 530 may be formed on a bottom surface of the housing 500. The exhaust hole 530 is connected to an exhaust line 540. The exhaust line 540 may be equipped with a depression member (not illustrated). The depression member (not illustrated) may be any of the known pumps that provide negative pressure. Process gases and process impurities supplied to the treatment space 501 may be discharged from the treatment space 501 through the exhaust hole 530 and the exhaust line 540 sequentially. Additionally, the decompression member (not illustrated) provides negative pressure, so that the pressure in the treatment space 501 may be regulated.

On top of the exhaust hole 530, an exhaust baffle 550 may be disposed, which functions to provide more uniform exhaust to the treatment space 501. The exhaust baffle 550 may be positioned between the sidewall of the housing 500 and the support unit 600 described later. The exhaust baffle 550 may have a generally ring shape when viewed from above. The exhaust baffle 550 may be formed with at least one baffle hole 552. The baffle hole 552 may penetrate the top surface and the lower surface of the exhaust baffle 550. Process gas and process impurities of the treatment space 501 may flow through the baffle hole 552 to the exhaust hole 530 and the exhaust line 540.

The support unit 600 supports the substrate W while the treatment process is in progress in the state where the substrate W is seated. Further, the support unit 600 may cool or heat the substrate W according to the process processing condition, or raise or lower the substrate W when the substrate W is loaded and unloaded. The support unit 600 is disposed on the interior of the housing 500. The support unit 600 may be disposed within the treatment space 501. The support unit 600 may be disposed a certain distance upwardly from the bottom surface of the housing 500. The support unit 600 supports the substrate W. The support unit 600 may include an electrostatic chuck which adsorbs the substrate W by using electrostatic force. In contrast, the support unit 600 may support the substrate W by using a variety of methods, such as vacuum adsorption or mechanical clamping. In the following, the support unit 600 including an electrostatic chuck is described as an example.

As one example of the support unit 600, the support unit 600 may include an electrostatic chuck 610, a ring member 640, an insulating plate 650, and a lower cover 660.

The electrostatic chuck 610 supports the substrate W. The electrostatic chuck 610 may include a dielectric plate 620 and a base plate 630.

The dielectric plate 620 is located at the top of the support unit 600. The dielectric plate 620 may be a disk-shaped dielectric substance. The substrate W is placed on a top surface of the dielectric plate 620. According to the exemplary embodiment, the top surface of the dielectric plate 620 may have a smaller radius than the substrate W. When the substrate W is placed on the top surface of the dielectric plate 620, an edge region of the substrate W may be located outside the dielectric plate 620.

Furthermore, the dielectric plate 620 includes electrodes 621 and heaters 622 disposed therein. According to the exemplary embodiment, the electrode 621 may be positioned above the heater 622 in the interior of the dielectric plate 620. The electrode 621 is electrically connected to a first power source 621a. The first power source 621a may include a DC power source. A first switch 621b is installed between the electrode 621 and the first power source 621a. When the first switch 621b is turned on, the electrode 621 is electrically connected to the first power source 621a, and direct current flows through the electrode 621. Electrostatic force is exerted between the electrode 621 and the substrate W by the current flowing through the electrode 621. Accordingly, the substrate W is adsorbed on the dielectric plate 620.

Additionally, the dielectric plate 620 may have at least one first flow path 623 formed therein. The first flow path 623 may be formed from a top surface of the dielectric plate 620 to a bottom surface of the dielectric plate 620. The first flow path 623 may be configured in communication with a second flow path 633 where the second flow path 633 is formed, or when the second flow path 633 is not formed, the first flow path 623 may be configured in communication with the first supply line 632c. The first flow paths 623 may be formed spaced apart from each other in the center region of the dielectric plate 620 and the edge regions surrounding the center region, when viewed from above. The first path 623 functions as a passageway through which helium gas is supplied to the bottom surface of the substrate W.

The base plate 630 is positioned below the dielectric plate 620. The base plate 630 may have a disk shape. The top surface of the base plate 630 may be stepped such that the center region is higher than the edge region. The center region of the upper portion of the base plate 630 may have an area corresponding to the bottom surface of the dielectric plate 620. The center region of the upper portion of the base plate 630 may be bonded to the bottom surface of the dielectric plate 620. The ring member 640, which is described later, may be located on top of the edge region of the base plate 630.

The base plate 630 may include a conductive material. For example, the material of the base plate 630 may include aluminum. The base plate 630 may be electrically connected to a third power source 630a. The third power source 630a may be a high frequency power source that generates high frequency power. For example, a high frequency power source may be an RF power source. The RF power source may be a high bias power RF power source. The base plate 630 receives high frequency power from the third power source 630a. As a result, the base plate 630 may function as an electrode that generates an electric field. According to the exemplary embodiment, the base plate 630 may function as a lower electrode of a plasma source described later. However, by way of limitation, the base plate 630 may be grounded and function as a lower electrode.

Additionally, the second flow path 633 and a cooling path 634 may be further formed on the interior of the base plate 630.

The second flow path 633 may be a passageway through which the helium gas circulates. The second flow path 633 is connected to a first supply source 632a via the first supply line 632c. The first supply source 632a stores helium gas. The second flow path 633 optionally further includes a helically shaped first circulation path 632 formed on the interior of the base plate 630, and the first circulation path 632 may supply helium gas to the second flow path 633 via the first supply line 632c. On the other hand, the helium gas supplied to the second flow path 633 may include various types of gases or liquids. Helium gas may be a fluid supplied to the lower surface of the substrate W to eliminate temperature non-uniformity of the substrate W while performing plasma treatment on the substrate W. A first valve 632b is installed in the first supply line 632c. The first valve 632b may be an open/close valve. Depending on the opening and closing of the first valve 632b, helium gas may be selectively supplied to the first circulation path 632. The second flow path 633 is in fluid communication with the first circulation path 632 and the first flow path 623. Helium gas supplied to the first circulation path 632 may be supplied to the bottom surface of the substrate W by sequentially passing through the second flow path 633 and the first flow path 623. On the other hand, the second flow path 633 and the first circulation path 632 may be optionally formed, and when the second flow path 633 and the first circulation path 632 are not formed, the first flow path 623 may be directly connected to the first supply line 632c to be supplied with helium gas.

The cooling path 634 may be a passage through which the heat exchange fluid circulates. In this case, the heat exchange fluid may include a refrigerant, which is a known fluid utilized in a heat exchanger. The cooling path 634 may have a spiral shape. Additionally, the cooling paths 634 may be arranged such that ring-shaped paths having different radii share the same center.

The ring member 640 is disposed in the edge region of the electrostatic chuck 610. In one example, the ring member 640 may be a focus ring. The ring member 640 has a ring shape. The ring member 640 is disposed along the circumference of the dielectric plate 620. For example, the ring member 640 may be disposed on an upper side of an edge region of the base plate 630.

The top surface of the ring member 640 may be stepped. According to the exemplary embodiment, an inner portion of the top surface of the ring member 640 may be located at the same height as the top surface of the dielectric plate 620. Further, the inner portion of the top surface of the ring member 640 may support the bottom surface of the edge region of the substrate W located outside of the dielectric plate 620. An outer portion of the top surface of the ring member 640 may surround a lateral surface of the edge region of the substrate W.

The insulation plate 650 is located on the underside of the base plate 630. The insulation plate 650 may include an insulating material. The insulating plate 650 electrically insulates the base plate 630 and the lower cover 660 described later. The insulating plate 650 may have a substantially disk-like shape when viewed from above. The insulating plate 650 may have an area corresponding to the base plate 630.

The lower cover 660 is located on the underside of the insulating plate 650. The lower cover 660 may have a cylindrical shape with an open top surface when viewed from above. The top surface of the lower cover 660 may be covered by the insulating plate 650. In the interior space of the lower cover 660, a lift pin assembly 670 may be located for raising and lowering the substrate W.

In addition, the lower cover 660 may further include a plurality of connection members 662. The connection member 662 may connect an outer surface of the lower cover 660 to an inner wall of the housing 500. The plurality of connection members 662 may be spaced apart along a circumferential direction of the lower cover 660. The connection member 662 supports the support unit 600 on the interior of the housing 500. Additionally, the connection member 662 may be connected to the grounded housing 500 to ground the lower cover 660. Further, the connection member 662 may have a hollow shape with a space inside. A first power line 621c connected with the first power source 621a, a second power line 622c connected with the second power source 622a, a third power line 630c connected with the third power source 630a, the first supply line 632c connected with the first circulation path 632, and the lines and pipes connected with the cooling path 634 extend to the outside of the housing 500 through the space formed in the interior of the connection member 662.

The heater 622 heats the support unit 600 to raise the temperature of the support unit 600 and the substrate W so that impurities generated after completion of the plasma treatment of the substrate W may be easily removed. The heater 622 is electrically connected to the second power source 622a. A heater switch 622b is installed between the heater 622 and the second power source 622a. When the heater switch 622b is turned on, the heater 622 may be electrically connected to the second power source 622a. The heater 622 may generate heat by resisting the current supplied from the second power source 622a. The heat generated by the heater 622 is transferred to the substrate W via the dielectric plate 620. The substrate W placed on the dielectric plate 620 may be maintained at a predetermined temperature by the heat generated by the heater 622. The heater 622 may include a spiral-shaped coil. Further, the heater 622 may include a plurality of coils. Although not illustrated, the plurality of coils may be provided in different areas of the dielectric plate 620. For example, a coil for heating the center region of the dielectric plate 620 and a coil for heating an edge region of the dielectric plate 620 may each be buried in the dielectric plate 620, and the degree of heating between the coils may be independently regulated. Additionally, the heater 622 may include a plurality of heaters, and each of the plurality of heaters 622 may be selectively disposed within or around an entire region of the support unit 600, in addition to being inserted into the interior of the dielectric plate 620. In the example, the case where the heater is located inside the dielectric plate 620 has been described as an example, but the present disclosure is not limited thereto. For example, the heater 622 may not be located on the interior of the dielectric plate 620. Additionally, the heater 622 may be printed on the bottom surface of the dielectric plate 620, or may be located above the cooling path 634 in the inner center of the base plate 630. The heater 622 may minimize thermal shock to the support unit 600 because the heater 622 slowly raises the temperature of the support unit 600 by the heating nature of slowly increasing temperature.

The fluid supply unit 631 adjusts the temperature of the support unit 600 according to the treatment status of the substrate W to cool the substrate W and to prevent the temperature of the support unit 600 from rising after the treatment of the substrate W is completed.

As one example of the fluid supply unit 631, the fluid supply unit 631 may include a fluid supply valve 634a, a cooler 634b, an inner pipe 634c, a fluid return valve 634d, and a return-side inner pipe 634e.

The fluid supply valve 634a is connected between an inlet of the cooling path 634 and an outlet of the cooler 634b. The fluid supply valve 634a may be manually opened and closed. Alternatively, the fluid supply valve 634a may be formed as a valve whose opening and closing is controlled by a control signal and may open and close in an automatic manner. In this case, the fluid supply valve 634a may have an open or closed state controlled by the control unit 900. The fluid supply valve 634a may have opening and closing behavior depending on a state controlled by a preset algorithm by the control unit 900. The fluid supply valve 634a allows a heat exchange fluid to flow to the inlet side of the cooling path 634 when is opened, and blocks a heat exchange fluid from flowing to the inlet side of the cooling path 634 when is closed.

The cooler 634b includes an outlet through which the heat exchange fluid is discharged connected to the fluid supply valve 634a, and a return opening to collect the heat exchange fluid connected to the return side inner pipe 634e. The cooler 634b may be configured as an air-cooled heat exchanger, a condensing heat exchanger, a compression heat exchanger, or a thermoelectric heat exchanger to cool the heat exchange fluid. However, the present disclosure is not intended to limit the configuration of the cooler 634b to the above examples, and the cooler 634b may be implemented in various forms to cool the heat exchange fluid.

The inner pipe 634c has one end connected to the inlet of the cooling path 634, and the other end connected to the fluid supply valve 634a. The inner pipe 634c may be enclosed by the outer pipe 1, and the outer pipe 1 will be described in more detail below.

A fluid return valve 634d is connected between the return-side inner pipe 634e and a collection port of the cooler 634b. The fluid return valve 634d may be formed in the same configuration as the fluid supply valve 634a. The difference is that the fluid return valve 634d allows the heat exchange fluid to flow from the outlet side of the cooling path 634 to the cooler 634b side when is opened, and blocks the heat exchange fluid flowing from the outlet side of the cooling path 634 to the cooler 634b side when is closed.

The return side inner pipe 634e has one end connected to the inlet of the cooling path 634, and the other end connected to the fluid return valve 634d. The inner pipe 634c may be enclosed by the outer pipe 1, and the outer pipe 1 will be described in more detail below.

The fluid supply unit 631 may control the temperature of the heat exchange fluid flowing in the cooling path 634 so that a first treatment and a second treatment proceed at a temperature of 0° C. or less when the substrate W is treated. In this case, the first treatment may be a main etching treatment and the second treatment may be an over-etching treatment. In the first treatment, the fluid supply unit 631 may proceed with the first treatment with the heat exchange fluid within a first temperature range to cool the substrate W during the plasma treatment of the substrate W. Here, the first temperature range may be a cryogenic temperature range in which the main etching is performed, such as a temperature range lower than −20° C. For example, the fluid supply unit 631 may form the first temperature range of the heat exchange fluid to be from −30° C. to −60° C. when the substrate W is plasma treated, and proceed with the first treatment. Further, the fluid supply unit 631 may cause the substrate W to be treated within a second temperature range that is a temperature higher than the first temperature range of the heat exchange fluid after proceeding with the first treatment. Here, the second temperature range is a low-temperature temperature range for the over-etching, which may be a temperature range lower than 0° C. For example, the fluid supply unit 631 may form the second temperature range of the heat exchange fluid to be 0° C. to −30° C. when the substrate W is plasma treated. Accordingly, the substrate W may be plasma treated in a state cooled by each of the first temperature range and the second temperature range to improve the etch rate. Here, the temperature control during the first treatment and the second treatment may be regulated by the control unit 900 by controlling the fluid supply unit 631 to regulate the flow rate or flow volume of the heat exchange fluid.

The gas supply unit 700 supplies process gas to the treatment space 501. The gas supply unit 700 may include a gas supply nozzle 710, a gas supply line 720, and a gas supply source 730.

The gas supply nozzle 710 may be installed in a center region of the top surface of the housing 500. An injection port is formed in the bottom surface of the gas supply nozzle 710. The injection port (not illustrated) may inject process gas into the interior of the housing 500.

One end of the gas supply line 720 is connected to the gas supply nozzle 710. The other end of the gas supply line 720 is connected to the gas supply source 730. The gas supply source 730 may store process gas. The process gas may be gas that is excited to a plasma state by a plasma source, which is to be described later. According to the exemplary embodiment, the process gas may include NH3, NF3, and/or inert gas. Additionally, the gas supply source 730 may stop supplying the process gas to the treatment space and supply cleaning gas to remove impurities within the process chamber 50 after the plasma treatment. In this case, the cleaning gas may be gas containing active oxygen.

A gas valve 740 is installed in the gas supply line 720. The gas valve 740 may be an open/close valve. Depending on the opening and closing of the gas valve 740, process gas may be selectively supplied to the treatment space 501.

The plasma source excites the supplied process gas into a plasma state within the housing 500. The plasma source according to the exemplary embodiment of the present disclosure is a Capacitively Coupled Plasma (CCP). However, without limitation, Inductively Coupled Plasma (ICP) or Microwave Plasma may be used to excite the process gas supplied to the treatment space 501 into a plasma state. In the following, the case where a Capacitively Coupled Plasma (CCP) is used as the plasma source according to the exemplary embodiment will be described as an example.

The plasma source may include an upper electrode and a lower electrode. The upper electrode and the lower electrode may be disposed to face each other in the interior of the housing 500. One of the two electrodes may apply high frequency power and the other electrode may be grounded. In contrast, both electrodes may be supplied with high-frequency power. An electric field is formed in the space between the two electrodes, and the process gas supplied to the space may be excited into a plasma state. The substrate treatment process is performed by using plasma. According to the exemplary embodiment, the upper electrode may be an electrode plate 830 described later, and the lower electrode may be the base plate 630 described above.

A shower head unit 800 is positioned on top of the support unit 600 in the interior of the housing 500. The shower head unit 800 may include a shower plate 810, and a support unit 820.

The shower plate 810 is positioned on top of the support unit 600 to face the support unit 600. The shower plate 810 may be spaced apart in a downward direction from the ceiling surface of the housing 500. According to the exemplary embodiment, the shower plate 810 may have the shape of a disk having a constant thickness. The shower plate 810 is disposed a certain distance downwardly spaced from the ceiling surface of the housing 500, and a space may be formed between the shower plate 810 and the ceiling surface of the housing 500. Further, a plurality of holes 811 is formed in the shower plate 810. The plurality of holes 811 disperse and allow the process gas supplied from the gas supply nozzle 710 to pass through.

Further, the material of the shower plate 810 may include metal. The shower plate 810 may be grounded. In the present exemplary embodiment, the shower plate 810 is utilized as the upper electrode. However, the present disclosure is not limited to the case where the shower plate 810 is utilized as the upper electrode, and the upper electrode may be installed and configured as a separate electrode member.

The support unit 820 supports each of a side portion of the shower plate 810 and a side portion of the electrode plate 830. An upper end of the support unit 820 is connected with the ceiling surface of the housing 500, and a lower portion of the support unit 820 is connected with each of the side portion of the shower plate 810 and the side portion of the electrode plate 830. The material of the support unit 820 may include a non-metal.

The control unit 900 may control the configurations included in the process chamber 50. According to the exemplary embodiment, the control unit 900 may adjust an on state and an off state of the heater 622. Further, the control unit 900 may control the fluid supply unit 631. Specifically, the control unit 900 may control the first switch 621b, the fluid supply valve 634a, a first bypass valve 643b, and the cooler 634b. The control unit 900 controls the open/closed state of the fluid supply valve 634a and the open/closed state of the first bypass valve 643b to a first state or a second state. By controlling the above-described configurations, the control unit 900 may perform a substrate treatment method described below.

The control unit 900 may include a process control unit formed of a microprocessor (computer) that executes the control of the heater 622 and the fluid supply unit 631, a user interface formed of a keyboard in which an operator performs a command input operation or the like in order to manage the heater 622 and the fluid supply unit 631, a display for visualizing and displaying an operation situation of the heater 622 and the fluid supply unit 631, and the like, and a storage unit storing a control program for executing the process executed in the heater 622 and the fluid supply unit 631 under the control of the process control unit or a program, that is, a treating recipe, for executing the process in each component according to various data and treating conditions. Further, the user interface and the storage unit may be connected to the process control unit. The treatment recipe may be stored on a memory medium in the memory. The memory medium may include a removable disk, such as a hard disk, CD-ROM, or DVD, or semiconductor memory, such as flash memory.

In the following, the surrounding structure of the inner pipe 634c will be described in detail.

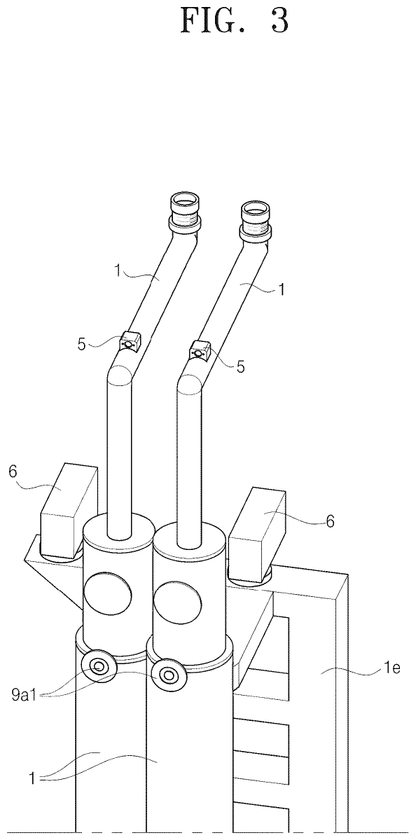

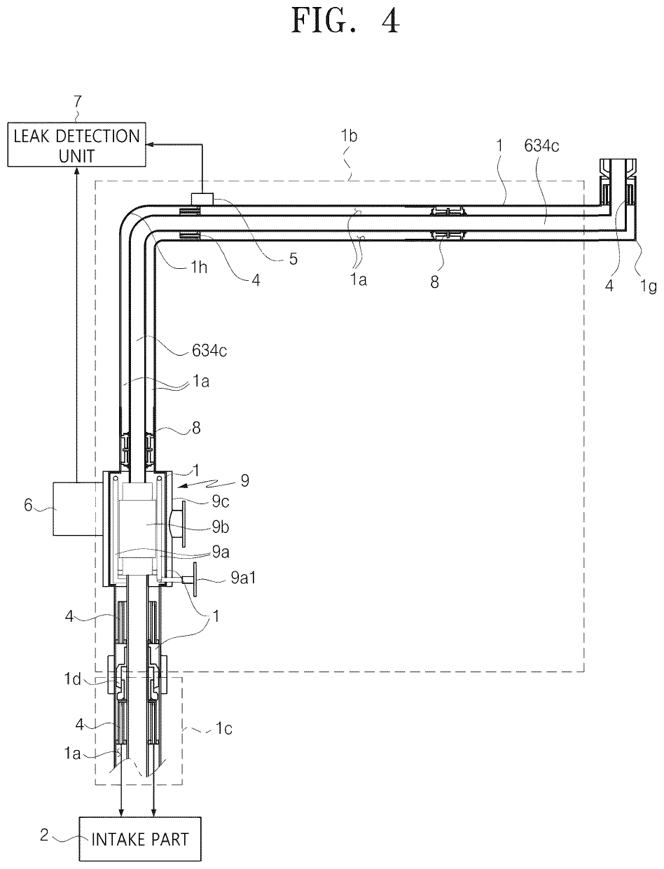

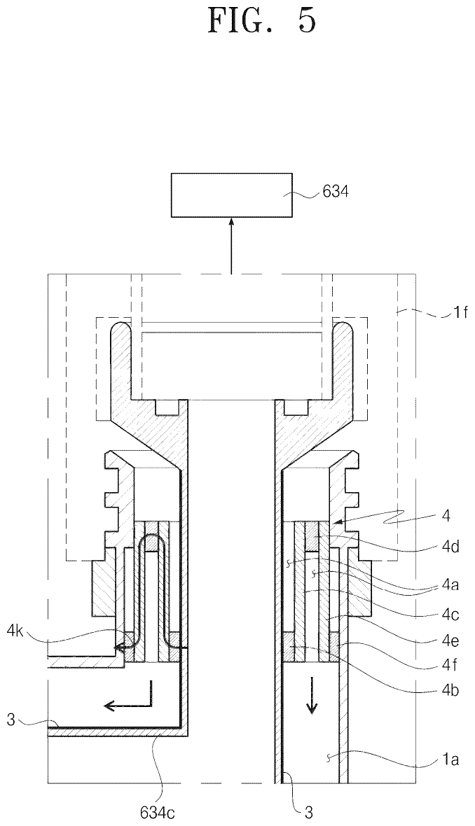

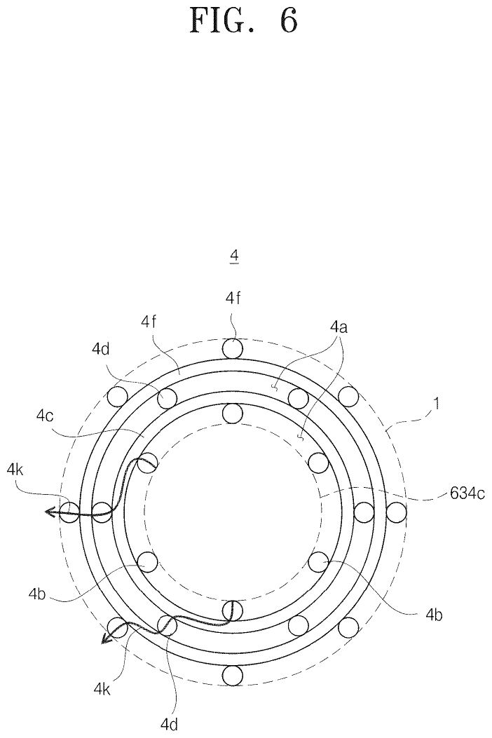

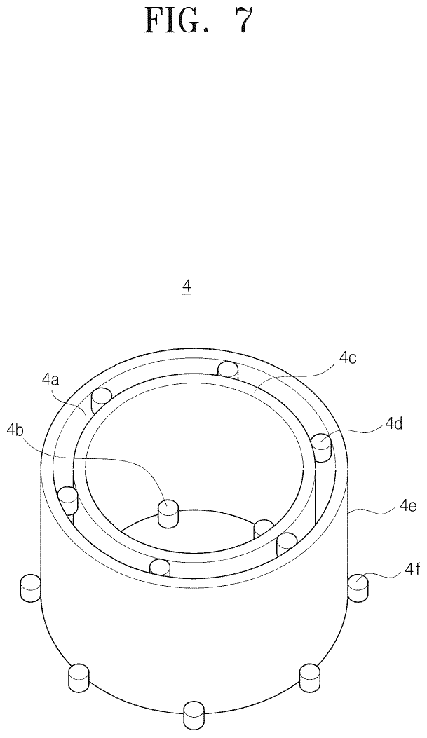

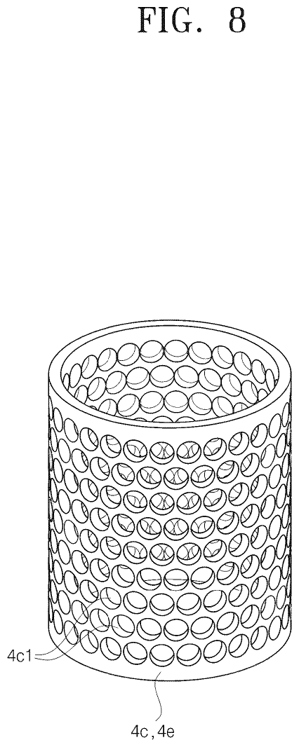

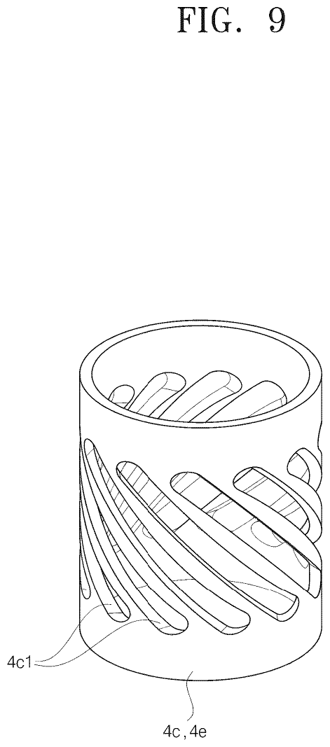

FIG. 3 is an enlarged perspective view of the peripheral structure of the inner pipe of the fluid supply unit and the collection side inner pipe according to the exemplary embodiment of the present disclosure. FIG. 4 is a partial cross-sectional view of the incised state of the inner pipe illustrated in FIG. 1. FIG. 5 is an enlarged partial cross-sectional view of a spacing maintaining part illustrated in FIG. 4. FIG. 6 is a top plan view of the spacing maintaining part illustrated in FIG. 5. FIG. 7 is a perspective view of the spacing maintaining part illustrated in FIG. 6. FIG. 8 is a perspective view of a modified example of a first can body illustrated in FIG. 7. FIG. 9 is a perspective view of a modified example of a second can body illustrated in FIG. 7.

Referring further to FIGS. 3 to 9, the fluid supply unit of the present disclosure may be formed by further including an outer pipe 1, an intake part 2, an insulation part 3, a spacing maintaining part 4, a temperature sensor unit 5, a pressure sensor unit 6, and a leak detection unit 7.

The outer pipe 1 is formed in the shape of a tubular body. In this case, the outer pipe 1 is disposed to surround the inner pipe 634c. The outer pipe 1 is disposed so as not to be in contact with the inner pipe 634c. Accordingly, a suction space la is formed between the outer pipe 1 and the inner pipe 634c. This suction space 1a is hermetically formed, and inside air is continuously sucked by the intake part 2. Here, the outer pipe 1 may be formed of a rigid material or a flexible material. Furthermore, the outer pipe 1 may be separated into a state composed of a rigid material and a state composed of a flexible material, and the outer pipes 1 separated by the different materials may be joined by a pipe fastening body 1d. In the case of the present exemplary embodiment, the outer pipe 1 is exemplified as being formed including a rigid region 1b formed of a rigid material, a flexible region 1c formed of a flexible ductile configuration, and the pipe fastening body 1d that fastens the rigid region 1b and the flexible region 1c. Furthermore, the outer pipe 1 may be formed in a form in which the rigid region 1b is connected by welding while being separated at certain intervals. Furthermore, an auxiliary fastening body le, such as a bracket or clamp, for supporting the outer pipe 1 may optionally be further formed on the outer side of the outer pipe 1, a detailed description of the auxiliary fastening body le will be omitted so as not to obscure the gist of the invention. Furthermore, the outer pipe 1 is connected to the support unit 600 by a connection part, in which case the connection part 1f may be configured in various forms, such as a combination of a socket and a packing, so that the suction space la is sealed when connected to the support unit 600. Additionally, the connection part lf may be configured to surround the inner pipe 634c along with the outer pipe 1.

The intake part 2 is connected to the suction space 1a, and sucks the suction space 1a. For example, the intake part 2 may be formed with a vacuum pump or a ring blower that sucks air. Thus, the intake part 2 may form a vacuum in the suction space 1a, and may suck and remove moisture generated by condensation on the outer side of the inner pipe 634c. Thus, the outer pipe 1 is prevented from having condensation on the exterior surface without having an insulating material wrapped around the exterior surface. In this case, the intake part 2 may be operated continuously to suck moisture in the suction space 1a.

The insulating part 3 surrounds the outer side of the inner pipe 634c. In this case, the insulation part 3 may be configured in the form of a sheath or tape wrapped or coated around the outer side of the inner pipe 634c. The insulation part 3 prevents the heat exchange fluid in the inner pipe 634c from conducting heat to the outer side. The insulating part 3 may be configured to hermetically wrap the entire outer surface of the inner pipe 634c, or may be selectively configured along certain sections of the inner pipe 634c as needed.

The spacing maintaining part 4 is disposed in the suction space la and provides support between the inner pipe 634c and the outer pipe 1. The inner pipe 634c and the outer pipe 1 are disposed at a certain interval apart by the spacing maintaining part 4 and are formed so that the inner pipe 634c and the outer pipe 1 are not in contact with each other. In this case, the inner pipe 634c and the outer pipe 1 are prevented from directly conducting heat by the spacing maintaining part 4. Thus, the outer pipe 1 is prevented from being directly heated by the inner pipe 634c, and thus, condensation is prevented from forming on the outer side of the outer pipe 1. Furthermore, the spacing maintaining part 4 may be formed in plural, each of which may be spaced apart in the suction space 1a.

Furthermore, the spacing maintaining part 4 spaces the inner pipe 634c in a certain range of the suction space 1a so that the center axis of the inner pipe 634c is aligned or adjacent to the center axis of the outer pipe 1. For example, the spacing maintaining part 4 may be formed as a circular structure having a certain diameter that surrounds the inner pipe 634c. In this way, when the center axes of the inner pipe 634c and the outer pipe 1 are matched, the position of the outer pipe 1 may be formed at a position in a predetermined error range when the outer pipe 1 is coupled to the support unit 600 or coupled to the connection part of the cooler 634b. Thus, the outer pipe 1 may be very easily connected and coupled when coupled to the support unit 600 or coupled to the cooler 634b. If the outer pipe 1 is not disposed so that its center axis is adjacent to the center axis of the inner pipe 634c, the coupling position is not specified, which may lead to connection defects, and in particular, the connection region of the inner pipe 634c may be gapped when a contraction of the inner pipe 634c occurs.

Furthermore, the spacing maintaining part 4 is formed with a passage area 4a that allows the suction spaces 1a located on both sides of the spacing maintaining part 4 to communicate with each other. Thus, the spacing maintaining part 4 may keep the inner pipe 634c and the outer pipe 1 apart so that the inner pipe 634c and the outer pipe 1 are not in contact with each other, while allowing suck of the intake part 2 to occur throughout the suction space 1a through a passage area 4a.

Further, the spacing maintaining part 4 may be coupled to the inner pipe 634c and coupled to the outer pipe 1. Here, the spacing maintaining part 4 may be coupled to the inner pipe 634c and coupled to the outer pipe 1 by welding. Thus, the spacing maintaining part 4 is fixed in position and not displaced in the event that the inner pipe 634c shrinks and bends due to supercooling. Thus, since the spacing maintaining part 4 is always disposed in a predetermined position, the inner pipe 634c and the outer pipe 1 are prevented from being burned out or deformed by movement of the spacing maintaining part 4.

Furthermore, although the spacing maintaining part 4 is formed so that the inner pipe 634c and the outer pipe 1 are not in direct contact with each other, by supporting the space between the inner pipe 634c and the outer pipe 1, cold air from the inner pipe 634c may be conducted to the outer pipe 1 side and cause condensation on the outer surface of the outer pipe 1. Accordingly, the spacing maintaining part 4 extends from the inner pipe 634c to the outer pipe 1 forming at least one bent path 4k. For example, the spacing maintaining part 4 may be disposed in a bent form having a plurality of bent portions over a vertical distance from the inner pipe 634c to the outer pipe 1. Thus, the spacing maintaining part 4, when cooled continuously by contact with the inner pipe 634c, may concentrate the cold air generated by the inner pipe 634c so that moisture generated by condensation that may occur on the entire outer surface of the inner pipe 634c may be concentrated toward the spacing maintaining part 4. In this case, the intake part 2 intensively absorbs the concentrated moisture formed in the bent path of the spacing maintaining part 4, thereby proactively preventing condensation from being generated on the outer surface of the outer pipe 1.

As one example of the spacing maintaining part 4 forming the bent path 4k, the spacing maintaining part 4 may be formed including a first connecting body 4b, a first cylindrical body 4c, a second connecting body 4d, a second cylindrical body 4e, and a third connecting body 4f.

The first connecting body 4b is coupled to the inner pipe 634c. In this case, the first connecting body 4b may be formed in a rod shape. Further, the first connecting body 4b may be coupled to the inner pipe 634c by a welding method. Further, the first connecting body 4b is formed only in a partial portion of the area between the inner pipe 634c and the first cylindrical body 4c. Thus, the first connecting body 4b may form a bent path from the inner pipe 634c to the first cylindrical body 4c.

The first cylindrical body 4c is coupled to the outer side of the first connecting body 4b. In this case, the first cylindrical body 4c may be formed in the shape of a circular cylinder. However, the present disclosure does not limit the shape of the first cylindrical body 4c to the above-mentioned shape, and of course, the first cylindrical body 4c may be transformed into various shapes depending on the shape or the arrangement structure of the inner pipe 634c. Furthermore, the first cylindrical body 4c may be coupled to the first connecting body 4b by a welding method. Further, the first cylindrical body 4c may be formed with a plurality of through-holes 4c1. Accordingly, the first cylindrical body 4c may improve the suction efficiency of moisture that may be generated on the side of the plurality of through-holes 4c1 during suction of the intake part 2. In this case, the shape of the through-hole 4c1 may be varied, such as a circular shape or an arc shape, such as the modified example illustrated in the drawings.

The second connecting body is coupled to the outer side of the first cylindrical body 4c. In this case, the second connecting body may be formed in a rod shape. Further, the second connecting body may be coupled to the first cylinder 4c by welding. Further, the second connecting body may be disposed so that the second connecting body does not overlap the first connecting body 4b and the third connecting body 4f when viewed in the direction of the outer periphery of the inner pipe 634c and the outer pipe 1. Accordingly, the first connecting body 4b, the first cylindrical body 4c, the second connecting body, the second cylindrical body 4e, and the third connecting body 4f form a path that bends multiple times toward the outer circumference of the inner pipe 634c, thereby increasing the area where moisture can be concentrated. Therefore, when cold air is thermally conveyed from the inner pipe 634c to the outer pipe 1, condensation is induced to occur near the path bent in multiple times of the first connecting body 4b, the first cylindrical body 4c, the second connecting body, the second cylindrical body 4e, and the third connecting body 4f and the intake part 2 sucks the condensation, thereby preventing condensation from occurring on the outer surface of the outer pipe 1.

The second cylindrical body 4e is coupled to the outer side of the second connecting body. In this case, the second cylindrical body 4e may be formed in the shape of a circular cylinder having a diameter larger than the diameter of the first cylindrical body 4c. However, the present disclosure does not limit the shape of the second cylindrical body 4e to the above-mentioned shape, and of course, the second cylindrical body 4e may be transformed into various shapes depending on the shape and the arrangement structure of the inner pipe 634c. Further, the second cylindrical body 4e may be coupled to the second connecting body by a welding method. Further, the second cylindrical body 4e may be formed with a plurality of through-holes 4c1. Accordingly, the second body 4e may improve the suction efficiency of moisture that may be generated on the side of the plurality of through-holes 4c1 during suction of the intake part 2. In this case, the shape of the through-hole 4c1 may be varied, such as a circular shape or an arc shape, such as the modified example illustrated in the drawings.

The third connecting body 4f is coupled between the outer side of the second cylindrical body 4e and the outer pipe 1. Furthermore, the third connecting body 4f may be coupled to only a partial portion of the area between the second connecting body 4e and the outer pipe 1. Thus, the third connecting body 4f may form a bent path from the outer pipe 1 to the second cylindrical body 4e.

Furthermore, by forming the aforementioned passage area 4a between the first connecting body 4b, the first cylindrical body 4c, the second connecting body, the second cylindrical body 4e, and the third connecting body 4f, it is possible to ensure that the suction of the intake part 2 is carried out throughout the suction space 1a through the passage area 4a.

While the above example illustrates two cylindrical bodies, the first cylindrical body 4c and the second cylindrical body 4e, the cylindrical bodies may include one or more as desired, and the first connecting body 4b, the second connecting body 4c, and the third connecting body 4f may be varied in a number corresponding to the number of cylindrical bodies. For example, when one cylindrical body is configured, only the first connecting body 4b and the second connecting body 4c connecting the inner pipe 634c and the outer pipe 1 may be configured, and when three cylindrical bodies are configured, the cylindrical bodies may be configured in various variations, such as the form in which the connecting body is coupled between the cylindrical bodies and the inner pipe 634c and the outer pipe 1.

The temperature sensor unit 5 is coupled to the outer pipe 1 and measures the temperature of the outer pipe 1. The temperature sensor unit 5 may be formed as a thermocouple (TC) temperature sensor or a rheostat (RTD) temperature sensor. In this case, the temperature sensor unit 5 may include a plurality of temperature sensor units and may be spaced apart on the outside of the outer pipe 1. The temperature sensor unit 5 is installed to detect leakage of the heat exchange fluid in the inner pipe 634c.

The pressure sensor unit 6 is connected in communication with the suction space la and measures the pressure in the suction space 1a.

The leak detection unit 7 is interlocked with the temperature sensor unit 5 and continuously receives the temperature value of the outer pipe 1 from the temperature sensor unit 5. In this case, the leak detection unit 7 generates a leak alarm of the heat exchange fluid when the temperature of the outer pipe 1 received from the temperature sensor unit 5 is lower than a preset temperature value. For example, the leak detection unit 7 may generate a leak alarm when the temperature value of the outer pipe 1 remains −50° C. or below and increases to −40° C. beyond a preset temperature value of −45° C. In this case, the leak detection unit 7 may set the preset temperature value differently depending on the process conditions of the first treatment and the second treatment of the substrate W. Thus, the leak detection unit 7 may easily detect a leakage condition of the inner pipe 634c in cooperation with the temperature sensor unit 5.

In addition, the leak detection unit 7 is interlocked with the pressure sensor unit 6 to continuously receive a pressure value in the suction space la input from the pressure sensor unit 6. Here, the leak detection unit 7 generates a leak alarm of the heat exchange fluid when the pressure value in the suction space la received from the pressure sensor unit 6 becomes greater than a preset pressure value. In this case, the leak detection unit 7 may also set the preset pressure value differently depending on the first treatment state and the second treatment state of the substrate W. Thus, the leak detection unit 7 may easily detect a leakage condition of the inner pipe 634c in cooperation with the pressure sensor unit 6.

Furthermore, the leakage detection unit 7 may be interlocked with the control unit 900 described above to transmit the leakage alarm for the leakage state, thereby enabling the control unit 900 to monitor the leakage state.

In this way, the substrate treating apparatus according to the exemplary embodiment of the present disclosure has a reduced outer diameter than the substrate treating apparatus in the related art because the outer pipe 1 is disposed on the outer side of the inner pipe 634c, and the suction space 1a is sucked by using the intake part 2, so that condensation does not occur without wrapping a separate heat preservation material on the outer side of the outer pipe 1, and no heat preservation material is used.

Hereinafter, an anti-bending part 8 disposed around the inner pipe 634c will be described.

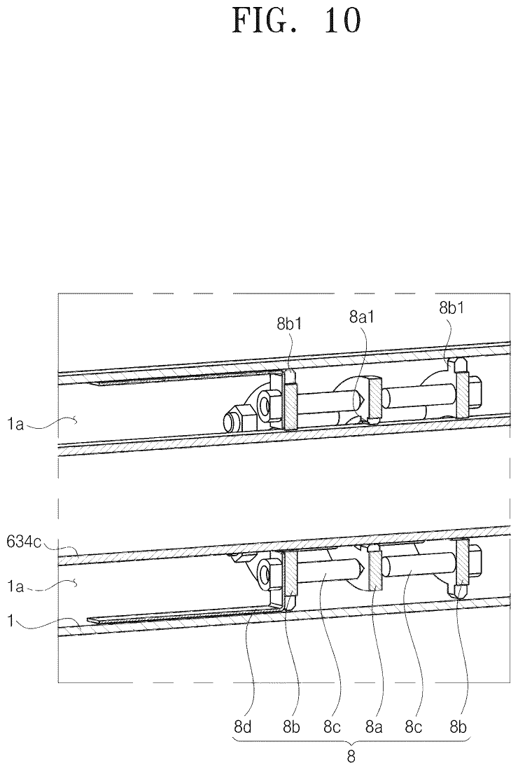

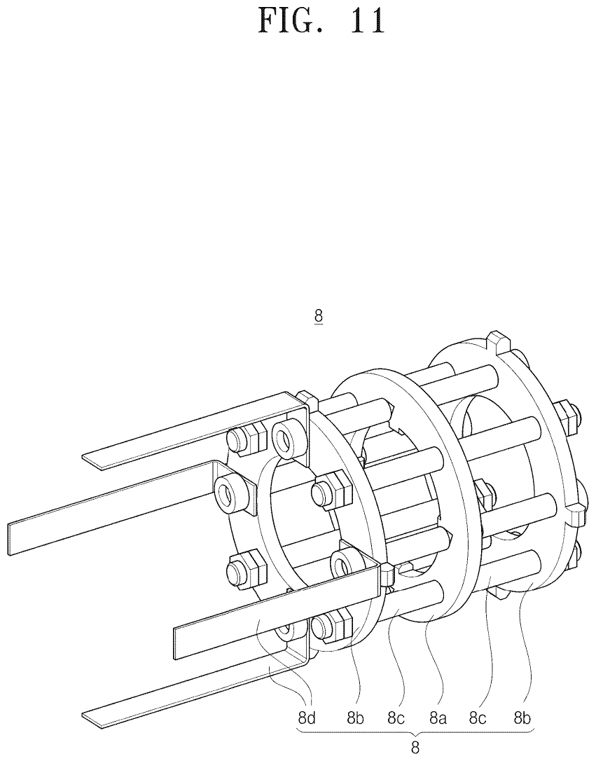

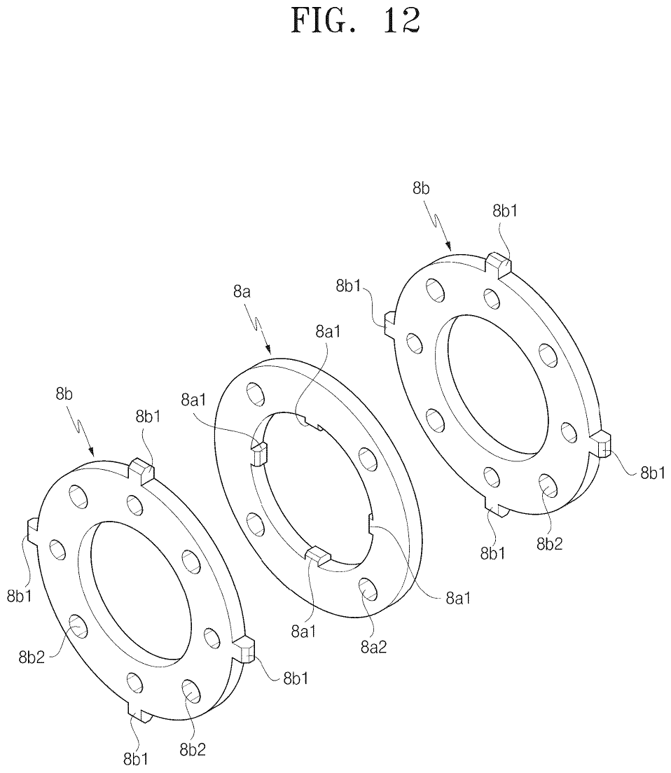

FIG. 10 is a partial cross-sectional view of an anti-bending part illustrated in FIG. 4, enlarged in the perspective direction. FIG. 11 is a perspective view of the anti-bending part illustrated in FIG. 10. FIG. 12 is an exploded perspective view of an inner support and an outer support of the anti-bending part illustrated in FIG. 11.

Referring further to FIGS. 10 to 12, the substrate treating apparatus according to the exemplary embodiment of the present disclosure may further including an anti-bending part 8.

The anti-bending part 8 is disposed in the suction space 1a and supports the inner pipe 634c while being coupled to the outer pipe 1. The anti-bending part 8 is disposed between areas where the inner pipe 634c and the outer pipe 1 are bent, thereby preventing the inner pipe 634c from being bent. In this case, the inner pipe 634c and the outer pipe 1 may be formed of a rigid material. For example, the inner pipe 634c and the outer pipe 1 may be formed from a metal material or a resin material. As such, the inner pipe 634c, which is formed of a rigid material, shrinks when supercooling occurs. In this case, the inner pipe 634c bends in the direction of the shrinkage due to the presence of bent regions. In particular, the inner pipe 634c bends more severely when the bent regions are formed toward different directions from each other. For example, upon shrinkage, the right region of the inner pipe 634c is bent in an upward direction of a bent right region 1g, and the left region of the inner pipe 634c is bent in a downward direction of a bent left region 1h, referring to FIG. 4. However, the anti-bending part 8 according to the exemplary embodiment of the present disclosure supports the inner pipe 634c while being coupled to the outer pipe 1, thus the anti-bending part 8 supports the inner pipe 634c to prevent the inner pipe 634c from bending when the inner pipe 634c shrinks due to supercooling.

As one example of the anti-bending part 8, the anti-bending part 8 may include an inner support 8a, an outer support 8b, a fastener 8c, and an outer coupling body 8d.

The inner support 8a is disposed to surround the inner pipe 634c. For example, the inner support 8a may be formed in the shape of a circular ring. Further, the inner support 8a may be in contact with the outer circumferential surface of the inner pipe 634c. In this case, the inner support 8a may have at least three first protrusions 8a1 protruding inwardly to be in contact with the inner pipe 634c. Here, the first protrusions 8a1 may be configured to be spaced apart from each other by a certain distance. As such, the first protrusion 8a1 provides supports so that the center axis of the inner pipe 634c is prevented from deviating from the center axis of the outer pipe 1. Further, the first protrusion 8a1 is minimized to the contact area of the inner pipe 634c and the inner support 8a, thereby preventing cold air from the inner pipe 634c from being transferred to the inner support 8a and the inner support 8a from being supercooled. Further, the inner support 8a may be formed of a metal material or a resin material. Furthermore, the inner support 8a may be formed with a plurality of first fastening holes 8a2 for insertion of the fastener 8c, such as a bolt.

The outer support 8b is disposed to surround the inner pipe 634c. For example, the outer support 8b may be formed in a ring shape. Further, the outer support 8b is in contact with the inner circumferential surface of the outer pipe 1. In this case, the outer support 8b may have at least three of the second protrusions 8b1 protruding outwardly to be in contact with the outer peripheral surface of the outer pipe 1. Here, the second protrusions 8b1 may be configured to be spaced apart from each other by a certain distance. The second protrusion 8b1 supports the inner circumferential surface of the outer pipe 1 so that the center axis of the inner pipe 634c is prevented from deviating from the center axis of the outer pipe 1. Furthermore, the second protrusion 8b1 is minimized to a contact area of the outer pipe 1 and the outer support 8b, thereby maximally preventing cold air from the inner pipe 634c from being transferred to the support of the outer pipe 1 and condensation from being generated in the outer pipe 1. Further, the outer support 8b may be configured in plural. In this case, the plurality of outer supports 8b may be disposed oppositely with the inner supports 8a interposed between. Further, the outer support 8b may be formed of a metal material or a resin material. Further, the outer support 8b may be formed with a plurality of second fastening holes 8b2 into which the fastener 8c, such as a bolt, may be inserted.

The inner support 8a and the outer support 8b support the area between the outer pipe 1 and the inner pipe 634c even when the inner pipe 634c is bent by shrinkage, thereby preventing the inner pipe 634c from being bent by shrinkage.

In this case, the inner support 8a and the outer support 8b are not limited to the foregoing examples, but may be installed with an optionally variable number of each as required.

The fastener 8c is coupled to the inner support 8a and the outer support 8b, so that the inner support 8a and the outer support 8b are fixed while being spaced apart by a certain distance. In the present exemplary embodiment, the fastener 8c may include a bolt and a nut, and in this case, the bolt may be engaged by the nut in the state a body has passed through a first fastening hole 8a2 and a second fastening hole 8b2. Further, the fasteners 8c is configured in plural to couple multiple sections of the inner support 8a and the outer support 8b, so that the inner support 8a and the outer support 8b may be restrained while being spaced apart from each other at a certain distance. Additionally, a portion of the fastener 8c is in close contact with the inner support 8a in the state of being coupled to the outer support 8b, to act as a spacer to separate the inner support 8a from the outer support 8b by a certain distance. On the other hand, the fastener 8c is not limited to the structure of the bolt and nut described above, and may be implemented in various variations in the form of coupling the inner support 8a and the outer support 8b. For example, the fastener 8c may have various coupling methods, such as a method of welding the inner support 8a and the outer support 8b, or a method of fitting the inner support 8a and the outer support 8b.

The outer coupling body 8d is coupled to at least one of the outer support 8b and the inner support 8a. For example, the outer coupling body may be formed of a plate that is bent in some areas, and may be bolted to the fastener 8c when the outer support 8b or the inner support 8a is bolted. In this case, the outer coupling body 8d may be configured in plural, and the plurality of outer coupling bodies 8d may be spaced apart from each other by a certain distance. Furthermore, the outer coupling body 8d is coupled to an inner circumference of the outer pipe 1. For example, the outer coupling body 8d may be welded to the inner circumference of the outer pipe 1. As such, the outer coupling body 8d is coupled to the outer support 8b and the inner support 8a and the outer pipe 1 to prevent the anti-bending part 8 from moving in the suction space la. Thus, the anti-bending part 8 is fixed to the area where the inner pipe 634c is most likely to bend due to shrinkage, to perform a function of preventing bending of the inner pipe 634c in a targeted location. If the anti-bending part 8 is not coupled to the outer pipe 1, the anti-bending part 8 moves to the bent region and plastically deforms the inner pipe 634c and the outer pipe 1, causing cracks in the inner pipe 634c and the outer pipe 1.

In this way, the anti-bending part 8 supports the inner pipe 634c and prevents the inner pipe 634c from bending inwardly of the outer pipe 1 in the event that shrinkage occurs between the regions where the inner pipe 634c and the outer pipe 1 bend and the inner pipe 634c bends toward the bent region.

In the following, a fuzzy port part 9 will be described.

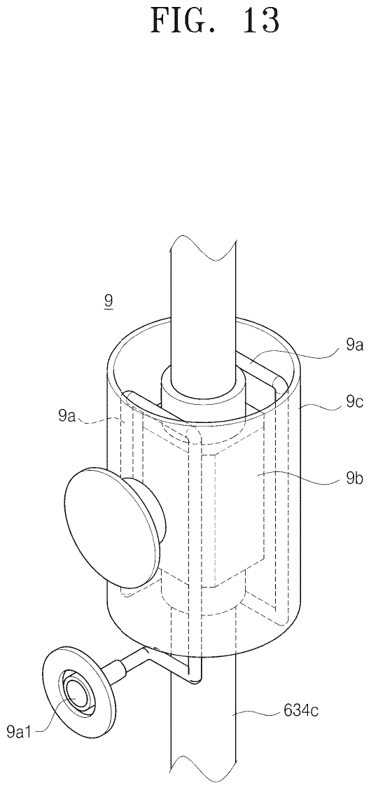

FIG. 13 is a perspective view of the interior of the outer pipe in which a purge port part illustrated in FIG. 3 is formed.

Referring further to FIG. 13, the substrate treating apparatus according to the exemplary embodiment of the present disclosure may further include a purge port part 9.

The purge port part 9 is a port connected with the inner pipe 634c to collect the heat exchange fluid by discharging the heat exchange fluid flowing in the inner side of the inner pipe 634c or by blowing the heat exchange fluid to the cooler 634b side. This purge port part 9 is for moving the heat exchange fluid flowing from the inner pipe 634c to the support unit 600 as needed, and has the characteristic of being connected to the inner pipe 634c and exposed outwardly to the exterior 1. Accordingly, in the purge port part 9 according to the exemplary embodiment of the present disclosure, a purge hole 9a1 at the other end is exposed outwardly in the state where one point of a pipe 9a for purge is connected to a branch point of the inner pipe 634c. In this case, the pipe 9a for purge of the purge port part 9 is connected to the inner pipe 634c, and cold air is transferred to the purge hole 9a1 side by the inner pipe 634c, so that condensation may be generated on the purge hole 9a1 side. Thus, the purge port part 9 according to the exemplary embodiment of the present disclosure forms a path bent in multiple times between the branch point of the inner pipe 634c and the purge hole 9a1, thereby minimizing the thermal conductivity from the inner pipe 634c toward the purge hole 9a1. In this way, the purge port part 9 may partially suppress condensation on the purge hole 9a1 side. Further, the purge port part 9 includes a reflector 9c installed to cover the bent path of the pipe 9a for purge that is formed between the branch point of the inner pipe 634c and the purge holes 9a1, so that cold air is not transferred to the outer pipe 1 side. Therefore, since the purge port part 9 blocks cold air to be transferred the outer pipe 1 side by the reflector 9c, it is possible to minimize condensation that may occur on the outer pipe 1 due to cooling of the pipe 9a for purge.

Describing one example of the purge port part 9, the purge port part 9 may include the pipe 9a for purge, a valve 9b for purge, and the reflector 9c.

The pipe 9a for purge is disposed between the suction spaces 1a. Furthermore, one end of the pipe 9a for purge may be connected to the branch point of the inner pipe 634c through the valve 9b for purge. In this case, the pipe 9a for purge may be arranged so that an area other than the branch point is not in contact with the inner pipe 634c, thereby minimizing the transmission of cold air from the inner pipe 634c. Furthermore, the pipe 9a for pipe has the purge hole 9a1 formed at the other end, and the purge hole 9a1 may be utilized for discharging the heat exchange fluid or sucking compressed air. In addition, the pipe 9a for pipe is configured in a form that surrounds the inner pipe 634c from the outer side of the inner pipe 634c or forms a form that bends multiple times from the outer side of the inner pipe 634c, thereby minimizing the thermal conductivity from the inner pipe 634c toward the purge hole 9a1. Furthermore, the outer pipe 1 located in the pipe 9a for purge may be expanded in size to occupy a larger volume than other areas.

The valve 9b for purge may be installed between the inner pipes 634c. In this case, the valve 9b for purge may be formed as a directional switchable manual valve, which may be opened and closed by an operator. The valve 9b for purge is formed in a closed state when the substrate W is treated to allow the heat exchange fluid to flow in the inner pipe 634c, and is switched to an open state by an operator who wishes to collect the heat exchange fluid, thereby communicating the inner pipe 634c and the pipe 9a for purge.

The reflector 9c is formed to wrap the pipe 9a for purge. For example, the reflector 9c may be formed as a cylinder that surrounds the pipe 9a for purge. The reflector 9c may utilize aluminum-coated insulation to facilitate radiating cold air. However, the present disclosure does not limit the material of the reflector 9c to the above examples, and the reflector 9c may be implemented in any form capable of radiating heat or cold air. Since the reflector 9c blocks cold air to the outer pipe 1, it is possible to minimize condensation that may occur on the outer pipe 1 due to cooling of the pipe 9a for purge.

On the other hand, while the outer pipe 1, the intake part 2, the insulation part 3, the spacing maintaining part 4, the temperature sensor unit 5, the pressure sensor unit 6, the leak detection unit 7, the anti-bending part 8, and the purge port part 9 are illustrated as being formed on the periphery of the inner pipe 634c, they may also be configured on the collection side inner pipe 634c, and a redundant description thereof will be omitted.

As described above, the present disclosure has been described with reference to the specific matters, such as a specific component, limited exemplary embodiments, and drawings, but these are provided only for helping general understanding of the present disclosure, and the present disclosure is not limited to the aforementioned exemplary embodiments, and those skilled in the art will appreciate that various changes and modifications are possible from the description.

Therefore, the spirit of the present disclosure should not be limited to the described exemplary embodiments, and it will be the that not only the claims to be described later, but also all modifications equivalent to the claims belong to the scope of the present disclosure.

What is claimed is:

1. A substrate treating apparatus comprising:
a process chamber having a treatment space for treating a substrate;
an inner pipe connected to the process chamber and for supplying a heat exchange fluid to an interior of the process chamber;
a cooler connected to the inner pipe, and for cooling the heat exchange fluid and supplying the cooled heat exchange fluid to the inner pipe;
an outer pipe disposed on an outer side of the inner pipe while surrounding the inner pipe to form a suction space between the inner pipe and the outer pipe;
an intake part connected to the suction space, and for sucking the suction space; and
a spacing maintaining part disposed in the suction space, and for maintaining a spacing distance between the inner pipe and the outer pipe.

2. The substrate treating apparatus of claim 1, wherein the spacing maintaining part makes the inner pipe be spaced apart at a certain extent of the suction space to make a center axis of the inner pipe match or be adjacent to a center axis of the outer pipe.

3. The substrate treating apparatus of claim 1, wherein the inner pipe and the outer pipe is not in direct contact with each other.

4. The substrate treating apparatus of claim 1, wherein the spacing maintaining part is provided with a passage area formed so that the suction spaces located on both sides of the spacing maintaining parts communicate with each other.

5. The substrate treating apparatus of claim 1, wherein the spacing maintaining part extends while forming a path having at least one bent from the inner pipe to the outer pipe.

6. The substrate treating apparatus of claim 5, wherein the spacing maintaining part includes:
a connecting body coupled to each of the inner pipe and the outer pipe and formed in plural; and
a cylindrical body coupled between the connecting bodies.

7. The substrate treating apparatus of claim 6, wherein the connecting body is coupled only to a partial region when is coupled to the cylindrical body.

8. The substrate treating apparatus of claim 6, wherein the connecting bodies include at least two connecting bodies that are not aligned on the same line based on an outer peripheral direction of the inner pipe and the outer pipe.

9. The substrate treating apparatus of claim 6, wherein the cylindrical body is provided with a plurality of through-holes.

10. The substrate treating apparatus of claim 1, wherein the spacing maintaining part is coupled to the inner pipe and is coupled to the outer pipe.

11. The substrate treating apparatus of claim 1, further comprising:
a temperature sensor unit coupled to the outer pipe and for measuring a temperature of the outer pipe; and
a leak detection unit which is interlocked with the temperature sensor unit and generates a leak alarm when the temperature of the outer pipe falls below a preset temperature value.

12. The substrate treating apparatus of claim 1, further comprising:
a pressure sensor unit connected with the suction space while being in communication with the suction space, and for measuring a pressure of the suction space; and
a leak detection unit which is interlocked with the pressure sensor unit and generates a leak alarm when the pressure of the suction space is higher than a preset pressure.

13. The substrate treating apparatus of claim 1, further comprising:
a purge port part connected to a branch point of the inner pipe to purge a heat exchange fluid flowing in the inner pipe to an outer side of the outer pipe, and forming a path bent multiple times on the outer side of the inner pipe.

14. The substrate treating apparatus of claim 13, wherein the purge port part includes:
a valve for purge installed between the branch points of the inner pipe;
a pipe for purge having one end connected with the valve for purge and the other end exposed to an outer side of the outer pipe, and forming a path bent multiple times on the outer side of the inner pipe; and
a reflector placed in the suction space and wrapping around an outer side of the pipe for purge.

15. A unit for supplying a fluid, the unit comprising:
an inner pipe for supplying a heat exchange fluid;
a cooler connected to the inner pipe, and for cooling the heat exchange fluid and supplying the cooled heat exchange fluid to the inner pipe;
an outer pipe arranged to surround the inner pipe so as not to be in contact with the inner pipe, and forming a suction space between the inner pipe and the outer pipe;
an intake part connected to the suction space, and for sucking the suction space; and
an anti-bending part disposed in the suction space, coupled to the outer pipe, and supporting the inner pipe.

16. The unit of claim 15, wherein the anti-bending part is disposed between areas in which the inner pipe and the outer pipe are bent.

17. The unit of claim 15, wherein the inner pipe and the outer pipe are formed of a rigid material.

18. The unit of claim 15, wherein the anti-bending part includes:
an inner support which surrounds the inner pipe and is in contact with the inner pipe;
an outer support which surrounds the inner pipe and is in contact with the outer pipe; and
a fastener engaged with the inner support and the outer support to fix the inner support and the outer support to be spaced apart by a certain distance.

19. The unit of claim 18, wherein the anti-bending part further includes:
an outer coupling body coupled to at least one of the outer support and the inner support and coupled to the outer pipe.

20. A substrate treating apparatus comprising:
a process chamber having a treatment space for treating a substrate;
a support unit for supporting the substrate within the process chamber;
an inner pipe connected with the support unit and for supplying a heat exchange fluid to an interior of the support unit;
a cooler connected to the inner pipe, and for cooling the heat exchange fluid and supplying the cooled heat exchange fluid to the inner pipe;
an outer pipe disposed to surround the inner pipe so as not to be in contact with the inner pipe, forming a suction space between the inner pipe and the outer pipe, and being not in direct contact with the inner pipe;
an intake part connected to the suction space and for sucking the suction space;
a spacing maintaining part which includes a cylindrical body coupled to each of the inner pipe and the outer pipe, is formed with a plurality of connecting bodies and a plurality of through-holes, and is coupled only to a partial region between the connecting bodies, and which is disposed in the suction space, supports an area between the inner pipe and the outer pipe, is disposed while surrounding the inner pipe in a predetermined extent of the suction space to make a center axis of the inner pipe be adjacent to a center axis of the outer pipe, is formed with a passage area in communication with the suction space, and forms a path bent at least one time from the inner pipe to the outer pipe;
a temperature sensor unit coupled to the outer pipe and for measuring a temperature of the outer pipe;
a pressure sensor unit connected in communication with the suction space and for measuring a pressure of the suction space;
a leak detection unit which interlocks with the temperature sensor unit and generates a leak alarm when a temperature of the outer pipe falls below a preset temperature value, and interlocks with the pressure sensor unit and generates a leak alarm when a pressure in the suction space is higher than a preset pressure;
a purge port part including a valve for purge installed between branch points of the inner pipe, a pipe for purge having one end connected with the valve for purge and the other end exposed to an outer side of the outer pipe and forming a path bent multiple times on the outer side of the inner pipe, and a reflector disposed in the suction space and surrounding an outer side of the pipe for purge; and
an anti-bending part including an inner support, which is disposed while surrounding the inner pipe and is in contact with the inner pipe, an outer support, which is disposed while surrounding the inner pipe and is in contact with the outer pipe, a fastener, which is coupled to the inner support and the outer support and separates the inner support and the outer support by a certain distance to fix the inner support and the outer support, and an outer coupling body, which is coupled to at least one of the outer support and the inner support and is coupled to the outer pipe.
